(19) United States
(12) Patent Application Publication
(10) Pub. No.: US 2013/0244382 A1
(43) Pub. Date: Sep. 19, 2013

(54) HIGH PRECISION SELF ALIGNING DIE FOR EMBEDDED DIE PACKAGING

(71) Applicant: David Clark, Ipswich (GB)

(72) Inventor: David Clark, Ipswich (GB)

(73) Assignee: FlipChip international, LLC, Phoenix, AZ (US)

(21) Appl. No.: 13/618,363

(22) Filed: Sep. 14, 2012

Related U.S. Application Data
(60) Provisional application No. 61/535,308, filed on Sep. 15, 2011.

(51) Int. Cl. H01L 21/56

(52) U.S. Cl. CPC H01L 21/56
USPC 438/124

(57) ABSTRACT

An apparatus and process for self-aligning components for forming an embedded die package is disclosed. The process includes providing a planar printed wire board (PWB) substrate having registration pads and a component having contact pads and spaced alignment pads, wherein the alignment pads each have a solder cap, placing the component on the substrate such that the alignment pads are in coarse alignment with the registration pads, applying heat to the alignment and registration pads to reflow the solder caps to precisely align the pads; and reducing the temperature below the reflow temperature. The process further includes applying a backside outer layer lamination, forming first vias, forming redistribution conductors on an opposite surface of the substrate connecting to the vias, and applying a front side outer layer lamination over the opposite surface of the substrate, all at temperatures below the reflow temperature.

### CROSS REFERENCE TO RELATED APPLICATIONS

This application claims the benefit of priority of U.S. Provisional Application Ser. No. 61/535,308, filed Sep. 15, 2011, entitled High Precision Self Aligning Die for Embedded Die Packaging, the content of which is incorporated by reference herein in its entirety.

### BACKGROUND OF THE DISCLOSURE

1. Field of the Disclosure

The present disclosure generally relates to a structure and method for packaging semiconductor devices, and more particularly to a structure and method for electronic embedded device packaging and assembly within a printed wiring board (PWB).

2. State of the Art

Typically the embeddable component(s) are placed onto an internal layer of a PWB laminate substrate together with any necessary additional active, passive or discrete components. After the placement of the components, the additional external PWB laminate and dielectric layers are molded or laminated on top of the internal layer thereby embedding the components. Single or multiple module sites can be populated on the internal laminate substrate. Component placement onto the internal PWB laminate substrate is achieved using commercially available pick-and-place production assembly equipment.

Assembly of large PWB substrate sizes with multiple embedded die PWB's in a step and repeat format is desirable to improve economy of scale. It is also desirable to increase component density in order to reduce total package footprint.

In typical embedded die manufacturing processes, component position is difficult to maintain post placement. For example, outer layer lamination and thermal curing steps can lead to component positional drift during the package build up process steps.

In embedded die applications, the PWB and component interconnect vias are typically formed by means of laser ablation process through the PWB build-up layers to expose contact pads, interconnects are then typically formed by way additive copper plating processes. Thus, the component contact pad size has to achieve a minimum dimension, typically 150 μm, define by the laser spot size and component placement tolerances associated with the SMT (surface mount technology) equipment.

Therefore there is a need for an apparatus and method for precise alignment of the die components prior to performing the buildup process operations.

### BRIEF DESCRIPTION OF THE DRAWINGS

The disclosure will be better understood and features and objects of the disclosure, including those set forth above, will become apparent when consideration is given to the following detailed description. Such description makes reference to the accompanying drawings wherein:

FIG. 1 illustrates a schematic sequence of a typical process flow for buildup of an embedded die package in accordance with the present disclosure.

FIG. 2 is a plan view of a component used in a PWB embedded die assembly showing alignment pads outside the contact pads in accordance with the present disclosure.

FIG. 3 is a cross sectional view of the component taken along the line 3-3 in FIG. 2.

FIG. 4 is a plan view of a portion of a PWB core substrate in accordance with the present disclosure to which the component in FIG. 1 is attached.

FIG. 5 is a schematic sectional view of the final embedded die package.

### DETAILED DESCRIPTION

In the following description, numerous specific details are set forth in order to provide a more thorough disclosure. It will be apparent, however, to one skilled in the art, that the art disclosed may be practiced without these specific details. In some instances, well-known features may have not been described in detail so as not to obscure the art disclosed.

Embodiments in accordance with the present disclosure enable increased package integration and density through high precision component placement for embedded PWB (printed wiring board) electronic package applications. In embedded PWB applications, the component or components are embedded within the multi-layer PWB build-up structure. This embedded die PWB in accordance with the present disclosure can significantly reduce total package height and offer enhanced component density and reduce package footprint.

Increased component density through this embedding innovation results in decreased interconnect path length which can assist in reducing parasitics and ultimately lead to improve overall package and system performance. The component placement accuracy is a limiting factor to increase component density and the final packaging density in the embedded die PWB.

Accurate component placement onto the internal laminate is essential to ensure high manufacturing yields associated with the subsequent process steps, particularly creation of the PWB blind laser vias, involved in forming the package or system interconnects. The component placement accuracy of production SMT (surface mount technology) pick-and-place assembly equipment is typically ±25 μm. Enhanced placement accuracy may be achievable at the compromise of placement speed and equipment throughput.

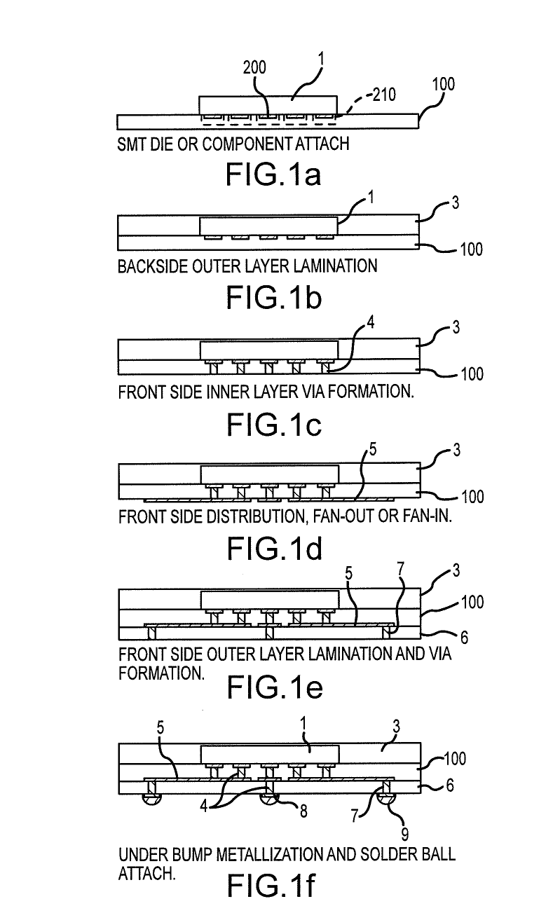

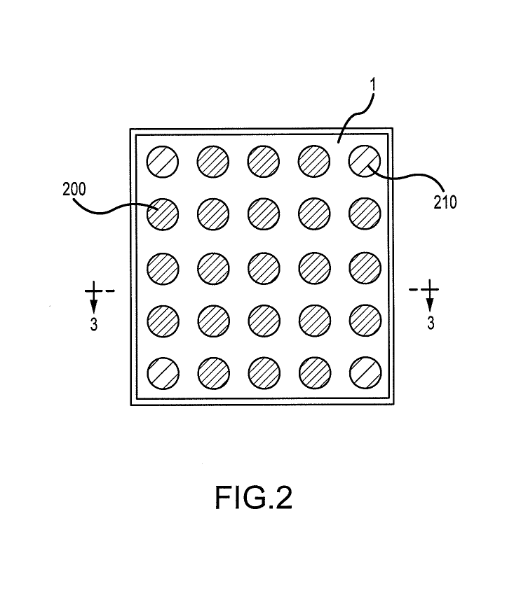

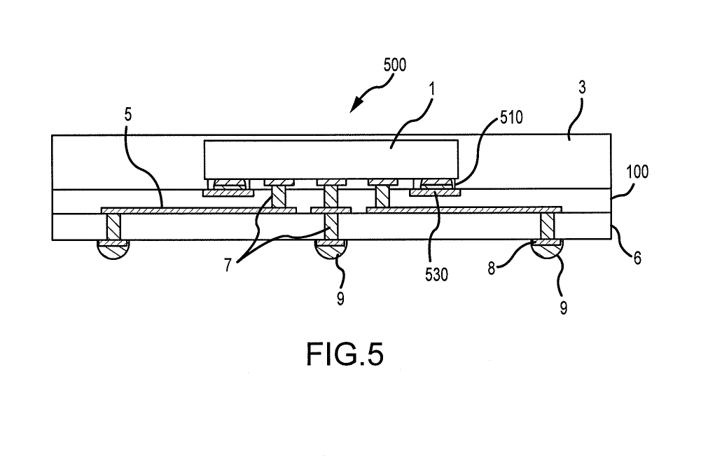

The precision placement of a component 1 on a PWB core substrate 100 in accordance with the present disclosure is facilitated by providing a preferably bounding set of alignment pads 210 on the mounting surface of the component 1, positioned around the active contact pads 200 of the component 1. There could be 2, 3, 4, or any number of alignment pads so long as they precisely define the location of the component 1 on the core substrate 100. A set of 4, one adjacent each corner, is preferred for rectangular shaped component packages. FIG. 2 is a separate bottom view of a component 1, in plan view, used in an PWB embedded die assembly shown in FIGS. 1 and 5 in accordance with the present disclosure.

Component 1 has contact pads 200 used for both electrical interconnect and also serving as an end-stop in the laser via creation process. Note that these pads 200 have no solder cap. Additional alignment pads 210 are shown located in the component corners, these alignment pads 210 each have a solder cap.

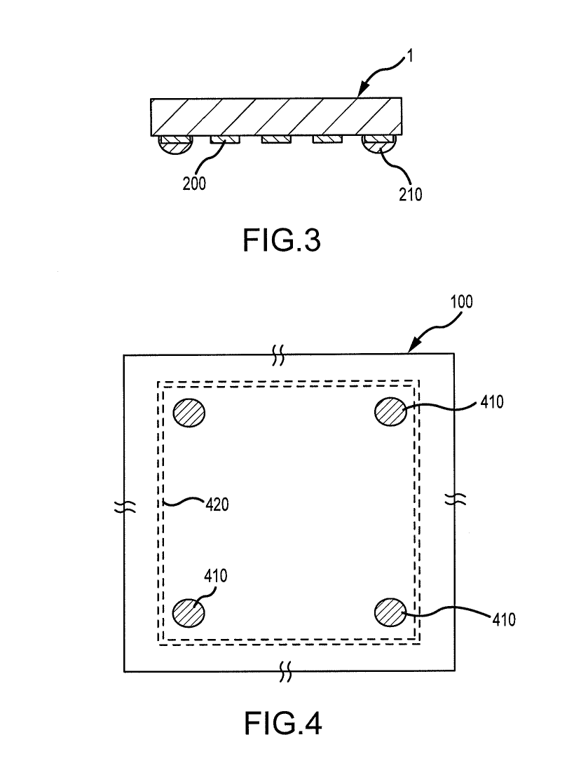

FIG. 3 illustrates the same component 1, in cross-section. The pads 200 used for electrical interconnect between the component 1 and PWB are shown solid. The pads 210 used to facilitate the self-alignment process are capped with solder as shown and are located in the corners of the component 1. This corner location is preferred, but it is to be understood that other layout configurations may also be used. All pads 200 and 210 used for electrical interconnection and component alignment are confined within the footprint of the component 1.

FIG. 4 Illustrates, in plan view, a portion of the PWB core substrate 100 to which the component 1 is ultimately attached. The receiving PWB core substrate 100 has Cu OSP (Copper Organic Solderability Preservative) or Ni/Au registration pads 410 which correspond in absolute position to the alignment pads 210 on the component 1 shown in FIGS. 2 and 3. The final assembled component position on the PWB core substrate 100 is also illustrated by dashed lines 420.

The first assembly operation of the process according to the present disclosure is that of providing the alignment pads 210 on the component 1 and the registration pads 410 on the PWB core substrate 100. When the components 1 are placed on the core substrate 100 of the PWB and the temperature of the solder caps raised to the melting point of the solder caps, the wetting of the alignment pads 210 and registration pads 410 via the solder reflow pulls the component 1 into precise alignment on the core substrate 100. Coarse placement accuracy was initially achieved via the SMT pick and place equipment. Fine placement accuracy is achieved via the solder reflow adhesion between the alignment pads 210 and registration pads 410. With the component 1 so aligned, precision placement is achieved within ±5 μm, a tolerance that has previously not been achievable in such processes. The reflow temperature is typically within a range of about 180° C. to about 230° C., depending on the particular solder alloy utilized. When the temperature is subsequently reduced to a level below the reflow range, which is maintained during the rest of the embedding process, this precision alignment is maintained by these soldered connections.

FIG. 1 Illustrates a typical process flow for an embedded die package construction in accordance with this disclosure. The embedded component 1 has been mounted by SMT and the soldered alignment connections 210 and 410 to the PWB core substrate 100 in FIG. 1a.

Electrical interconnects to the component 1 through the PWB core substrate 100 are formed by means of vias 4 and routing 5. During the following process, precise registration of component 1 and core substrate 100 is maintained via the solid solder connection between the alignment pads 210 and registration pads 410 as above described, since the temperatures utilized are below the solder reflow temperature.

FIG. 1 shows a sequence of steps or operations involved in the embedding process. In FIG. 1a, a SMT die or component 1 is first attached to a PWB core substrate 100. Note that alignment Cu pads 210 (separately shown in FIG. 2) are positioned around the die 1 at corner locations. These are shown in dashed lines in FIG. 1a.

Next, as shown in FIG. 1b, the back-side outer layer 3 is laminated over the component 1 on the PWB core substrate. This laminated outer layer 3 is vacuum deposited such that it reflows in and around each of the interconnect pads 200 and fills all the interstitial spaces. This layer 3 flows in and around the interconnect pads 200 and simultaneously embeds the component or die 1 after the flip chip attachment to the core substrate 100 described above, thus permanently bonding the die 1 within the embedded die structure. Next, as shown in FIG. 1c, the front-side inner layer vias 4 are formed through the PWB core substrate 100 so as to access the component interconnect pads 200.

FIG. 1d shows the next operation, in which the front side redistribution leads 5 are formed in place, either fan-out or fan-in from the vias 4 as per the particular design. FIG. 1e shows the front side outer layer lamination 6 and via 7 formation on the front side of PWB core substrate 100.

Finally, in FIG. 1f, formation of under bump metallization caps 8 and solder balls 9 are attached to the vias 7. This completes the assembly of the package 500.

FIG. 5 is a sectional schematic view through the final embedded package 500. The embedded component 1 has been mounted by SMT to the PWB core substrate 100. The component 1 has been self-aligned during the solder reflow process described above. A solder connection is made to the expose PWB Cu OSP pad 530 which is soldered to one of the interconnect alignment pads 210. Electrical interconnects to the component through the PWB are formed by means of vias 7 and routing 5.

The method in accordance with the present disclosure provides component high precision self-alignment for embedded die packages in PWB or other substrates. This method can achieve component placement accuracies within ±5 μm or better. This method also reduces risk for component movement, post SMT placement, commonly observed during subsequent package build up operations.

The method in accordance with this disclosure offers improved local and global component placement accuracy, and is applicable to either flex or rigid PWB substrates. The Cu post alignment interconnect pads 530 act as enhanced thermal heat sinks. Further, the solder capped alignment interconnect pads can act as a stress buffer for physical or thermal shock or during temperature cycling.

Various modifications and alternatives to the disclosed embodiments will be apparent to those skilled in the art. For example, the alignment interconnects may or may not be electrical interconnects and may or may not be placed in the component corners as shown. The process can be used in face-up or face-down embedded assembly process sequences. The pillar can be achieved using Nickel instead of copper for the standoff. In addition, one or multiple discrete, passive or active components may be packaged within the module above described. Accordingly, all such alternatives, variations and modifications are intended to be encompassed within the scope of and as defined by the following claims.

What is claimed is:

1. A method of embedded die packaging comprising:
providing a planar printed wire board (PWB) substrate with spaced component registration pads on one surface of the substrate;
providing a component having a plurality of contact pads in a predetermined spaced arrangement and a plurality of alignment pads each having a solder cap thereon;
placing the component on the substrate such that the alignment pads are in coarse alignment with the registration pads;
applying heat to the substrate to raise a temperature of the substrate to a reflow temperature of the solder caps to reflow the solder caps, thereby precisely aligning the alignment and registration pads;
reducing the temperature below the reflow temperature; and
applying a backside outer layer lamination over the component on the one surface of the substrate.

2. The method of claim 1 further comprising:
forming first vias through the substrate;
forming redistribution conductors on an opposite surface of the substrate connecting to the vias; and
applying a front-side outer layer lamination over the opposite surface of the substrate to complete the embedded die package.

3. The method of claim 2 further comprising forming second vias through the front-side outer layer lamination.

4. The method of claim 2 further comprising applying bump metallization and solder balls to the second vias.

5. The method of claim 1 wherein the backside lamination is applied at a temperature below the reflow temperature.

6. The method of claim 4 wherein the front side and the back side lamination layers are applied at a temperature below the reflow temperature.

7. A method of embedded die packaging comprising:
providing a planar printed wire board (PWB) substrate with spaced component registration pads on one surface of the substrate;
providing a component having a plurality of contact pads in a predetermined spaced arrangement and a plurality of alignment pads each having a solder cap thereon;
placing the component on the substrate such that the alignment pads are in coarse alignment with the registration pads;
applying heat to the substrate to raise a temperature of the substrate to a reflow temperature of the solder caps to reflow the solder caps, thereby precisely aligning the alignment and registration pads;
reducing the temperature below the reflow temperature;
applying a backside outer layer lamination over the component on the one surface of the substrate;
forming first vias through the substrate;
forming redistribution conductors on an opposite surface of the substrate connecting to the first vias;
forming second vias through the outer layer lamination; and
applying bump metallization and solder balls to the second vias.

8. The method of claim 7 wherein the backside outer lamination is applied at a temperature below the reflow temperature.

9. The method of claim 7 further comprising applying a front-side outer layer lamination over the opposite surface of the substrate to complete the embedded die package.

10. The method of claim 9 wherein the front side and the back side lamination layers are applied at a temperature below the reflow temperature.
